(19) United States
(12) Patent Application Publication
(10) Pub. No.: US 2019/0361511 A1
(43) Pub. Date: Nov. 28, 2019

(54) SYSTEM AND METHOD FOR INCREASING APPLIANCE CONTROL IN AN ELECTRICITY GRID

(71) Applicant: Embertec Piy Ltd, Dulwich (AU)

(72) Inventor: Domenico Gelonese, Dulwich (AU)

(21) Appl. No.: 16/417,432

(22) Filed: May 20, 2019

(30) Foreign Application Priority Data
May 23, 2018 (AU) 2018901804

(51) Int. Cl. G06F 1/3206; H02J 13/00; G01R 22/10

(52) U.S. Cl. CPC G06F 1/3206; H02J 2003/143; G01R 22/10; H02J 13/001

(57) ABSTRACT

A computer implemented system and method for demand management in an electricity supply network including aggregation of electricity use modification achieved by control of specific appliances and the provision of rewards to appliance control suppliers.

### FIELD OF THE INVENTION

The present invention relates to the field of energy demand management and control an electricity distribution network.

### BACKGROUND OF THE INVENTION

In a deregulated electricity market, energy utilities undertake to supply electricity to consumers. The energy utilities then source this electricity from energy generators who generate the electricity using a variety of power plants, each having its own running costs and lead time to come on stream.

The price which the energy utility pays the electricity generators for this electricity is affected by many factors including supply contracts and government regulation, but in general is driven by supply and demand. That is, in times of high demand, the price paid by the electricity utility increases. Demand varies continuously by time of day and time of year. The price variation may be many orders of magnitude, with for example, the marginal price of an additional kWh (kilowatt hour) varying from less than one cent to more than ten dollars.

Due to commercial realities and political constraints, and technical limitations, it is not possible for the energy utility to simply pass on the marginal cost directly to the consumer. The cost to the consumer of a kWh is generally fixed at a price significantly greater than the lowest marginal cost payable by the energy utility, but very much less than the maximum possible marginal cost payable by the energy utility, generally from less than ten to hundreds of cents per kWh. The consumer tariff may include coarse variation by time of day and time of year, with higher prices for periods expected to be peak demand periods, but there is no direct relationship between the marginal cost paid by an energy utility at a given time and the amount being paid by the consumer using that marginal kWh.

The energy utility may therefore be in a position where it would be profitable if the total consumption of electricity by all of the consumers supplied by the utility were to increase or decrease by a selected amount, within a short period of time, and for a limited duration. The energy utility will be willing to compensate the consumer for this change. However, they have no means to communicate with the consumer, either to make the offer or to know who has accepted it.

Consumers may be willing to decrease or increase their consumption, but they have little motivation to do so, and no means to know when to make such a change.

There have been efforts to bring about the required changes in demand by providing incentives for consumers to allow direct control of air conditioning units by the energy utility, allowing the utility to switch units off at peak demand times. However, there is strong consumer resistance to giving such arbitrary control to an electricity utility.

A suggested solution is for the energy utility to use price signalling, where the consumer price more closely tracks the price paid by the energy utility, with price changes potentially occurring frequently, in some cases as frequently as every one to sixty minutes. However, few consumers are prepared to make the effort to monitor the electricity price and make continual changes to consumption. The likely outcome is little permanent change in consumption patterns, but enormous consumer dissatisfaction with the increased electricity bills caused by using discretionary use appliances at times of high demand and hence high electricity prices.

It is known for discretionary use appliances to include remote control capability, allowing the appliances to be controlled remotely to respond to such price signals, but such capability increases the cost of the appliances, reducing the incentive for appliance suppliers to include the capability.

### SUMMARY OF THE INVENTION

In one form of this invention, a hub unit for installation in a household premises includes at least one wireless transceiver for communication with an appliance control module associated with at least one electricity consuming or generating appliance. The appliance control module is supplied by an appliance control supplier.

At least one transceiver communicates with a remote intelligent power manager. The hub unit receives operational data describing the operation and electricity consumption or generation of the appliance. The intelligent power manager receives from at least one participant in an energy market a price signal offering a value for a change in the amount of electricity to be supplied to or by the premises in an immediate future period, and processes the operational data and the price signal to determine an optimal operating regime for the appliance. This optimal operating regime is communicated to the hub unit from the intelligent power manager. The hub unit controls the appliance to change electricity consumption or generation to follow the optimal operating regime, and transmits power consumption data of the appliance describing the consequent change in electricity consumption to the intelligent power manager. The intelligent power manager records a value for the changed electricity consumption, and adds that value to a total for electricity consumption changes attributed to appliances from the supplier to permit the making of a value payment to the appliance control supplier proportional to the total electricity consumption changes attributed to appliances originating from the supplier.

The appliance control module may be incorporated into the appliance at manufacture, and the identified appliance control supplier may be a manufacturer of the appliance.

Alternatively, the appliance control module may be a control unit separate from the appliance, and the supplier of the control unit may be the identified appliance control supplier.

The invention also involves a system for control of at least one electricity consuming appliance in a household premises, including a hub in data communication with an appliance control module associated with the appliance. The appliance control module is supplied by an identified appliance control supplier. The hub receives electricity consumption data describing the electricity consumption of the appliance. The hub controls, at least in part, the electricity consumption of the appliance.

A processor acts as an intelligent power manager and receives a price signal from an electricity market offering a value for a change in the amount of electricity being consumed, or which will be consumed at some future time. The intelligent power manager also receives electricity consumption data of the appliance. The intelligent power manager analyses the electricity consumption data and the price signal to determine an operating profile which reduces the cost of operation of the appliance. The hub controls the appliance to implement the operating profile, and communicates to the intelligent power manager the consequent change in electricity consumption. The intelligent power manager records a value for the changed electricity consumption and adds that value to a total for electricity consumption changes attributed to appliances having an associated appliance control module from the appliance control supplier.

Preferably, the intelligent power manager effects a value payment to the appliance control supplier proportional to the total electricity consumption changes attributed to appliances control modules originating from that appliance control supplier.

The appliance control module may be incorporated into the appliance at manufacture, and the identified appliance control supplier may be a manufacturer of the appliance.

Alternatively, the appliance control module may be a control unit separate to the appliance, and the identified appliance control supplier may be the supplier of the appliance control unit.

The invention also involves a method for control of one or more electricity consuming appliances located in a household premises. An appliance control module controls at least one electricity consuming or generating appliance installed within the premises, the appliance control module being supplied by an identified appliance control supplier.

The method includes collecting operational data describing the operation and electricity consumption or generation of the appliance, and communicating the operational data to a remotely located intelligent power manager.

At least one participant in an energy market communicates a price signal offering a value for a change in the amount of electricity to be supplied to or by the premises in an immediate future period. The operational data and the price signal are processed to determine an optimal operating regime for the appliance, taking into consideration the value offered for the change in electricity supply or consumption.

The appliance is then controlled to change electricity consumption or generation to follow the optimal operating regime.

The consequent change in electricity consumption is recorded along with a value for the changed electricity consumption. The method includes adding that value to a total for electricity consumption changes attributed to appliances controlled by appliance control modules supplied by the appliance control supplier.

Preferably, the method further includes installing a hub unit in the premises which includes at least one wireless transceiver for communication with an appliance control module associated with the at least one electricity consuming or generating appliance. There is a transceiver for communication with a remote processor, being the intelligent power manager.

The method includes the hub unit controlling the appliance to change electricity consumption or generation to follow the optimal operating regime, and communicating to the intelligent power manager the consequent change in electricity consumption to be recorded and added to the total for electricity consumption changes attributed to appliances controlled by appliance control modules originating from the appliance control supplier.

Preferably, the method further includes making a value payment to the appliance control supplier proportional to the total.

The invention further involves a method for increasing the extent of load under control for a demand response system, including providing an incentive for appliance control suppliers to adapt appliances for participation in demand response events, and providing an intelligent power manager processor. The intelligent power manager records a value for changed electricity consumption attributable to an appliance participating in a demand response event, and adds that value to a total for electricity consumption changes attributed to appliances controlled by appliance control modules originating from the appliance control supplier. The intelligent power manager makes a value payment to the appliance control supplier proportional to that total.

### BRIEF DESCRIPTION OF THE DRAWINGS

FIG. 1 is a diagrammatic representation of the system of the invention.

FIG. 2 is a diagrammatic representation of a further version of the invention.

FIG. 3 is a flowchart of the process of recording the energy savings to be attributed to an appliance control supplier.

FIG. 4 is a diagrammatic representation of an Appliance Control Module.

FIG. 5 is a diagrammatic representation of an appliance incorporating an Appliance Control Module.

FIG. 6 is a diagrammatic representation of a hub with associated connections.

### DETAILED DESCRIPTION OF EXEMPLARY VERSIONS OF THE INVENTION

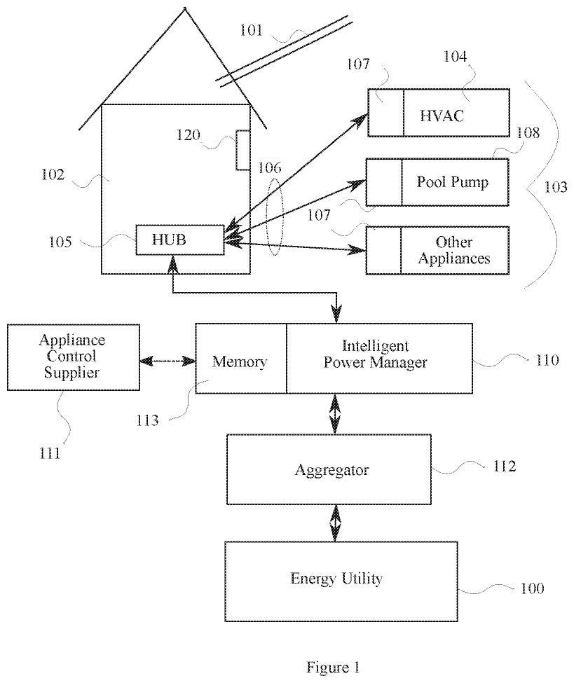

Referring to the illustrations and in particular to FIG. 1, an energy utility 100 is responsible for some part of the provision of electricity from electricity generators for supply to consumer premises 102. The electricity is provided to the consumer via electrical distribution grid 101. The energy utility 100 may perform different parts of the supply chain for supplying electricity to the consumer. The energy utility 100 may be, without limitation, one or more of an energy utility, a grid operator, an electricity generator, and an energy market regulator. In the version of FIG. 1, the electricity utility 100 is an energy retailer.

The consumer has a demand for electricity to power one or more appliances 103. The use, or degree of use, of at least some of these appliances 103 may be considered discretionary by the consumer. These may include such appliances as HVAC equipment 104 and swimming pool pumps 108. These appliances 103 may be termed discretionary use appliances. Such appliances 103 have a usage pattern which allows the overall function of the appliance to be achieved even with changes in the time or intensity of use.

Considering the example of a swimming pool pump 108, a consumer requires this to operate for a fixed amount of time per day, in order for the pool water to be properly filtered. However, the consumer generally has no requirement that the pump 108 be operating at specific times. So long as the total time of operation per day is met, the consumer does not care if the pump 108 operates during the day or at night, in a single continuous period, or a number of shorter periods.

In the case of HVAC equipment 104, the function the consumer requires is to keep a space at an acceptably comfortable temperature. In general, a consumer will select a temperature considered optimum. However, what is “acceptable” is subjective. Accordingly, a suitably motivated consumer may be prepared to allow the temperature to vary from the optimum in a direction which will cause the HVAC equipment 104 to consume less power.

This compares with non-discretionary appliances 103 such as refrigerators, freezers and basic lighting, where any variation in time of use or intensity of use will compromise the delivery to the consumer of the function of the appliance. For example, in order for a freezer to achieve its function of keeping food frozen and unspoiled, the freezer must consume energy to maintain a set temperature. Turning the freezer off, or allowing the set temperature to rise, will compromise this function.

The energy utility 100 sources the electricity which the consumer, and all of the other customers of the utility, require from electricity generators via an electricity market, which may take a number of forms.

For technical, commercial and political reasons, it is not generally possible for the energy utility 100 to implement a price regime where there is a direct, or even an approximate, relationship between the marginal cost per kWh paid by an energy utility 100 at a given time and the amount being paid by the consumer using that marginal kWh. Thus the wholesale price being paid by the energy utility 100 for the electricity is for the most part either significantly less than, or very much more than, the price which the consumer is charged for that electricity. This means there is a benefit to the utility 100 in changing the amount of electricity consumed at a given instant by its customer base. In particular, there is a significant benefit to the utility 100 in reducing energy consumption at peak times when the utility 100 is paying far more per kWh than it is able to charge its customers. There is also some benefit in increasing the amount of electricity the utility 100 is able to sell to its customers at times of low demand, when the utility 100 is able to buy electricity at prices far below the price charged to the consumer.

This means there is a benefit to the utility 100 in dynamically changing the power consumption of appliances 103 in the household according to the supply and demand, and electricity price position faced by the utility 100 at any point in time.

In order to obtain the cooperation of the consumer in achieving this change, the utility 100 must provide some benefit to the consumer for making or allowing the consumption change. In order for the change to be implemented in a dynamic manner, a signal must be provided to the consumer premises 102.

The communication to the consumer premises 102 is generically described as a price signal. The price signal may be a simple price movement—raising prices to curtail demand, lowering prices to increase demand—but this would be unusual, given the already mentioned political difficulties.

The price signal may be an offer to provide value in exchange for a change in consumption, which may be a specific payment for each unit of load reduced or added.

A hub 105 is provided in the consumer premises 102. The hub 105 includes a communication transceiver which allows the hub to communicate with corresponding transceivers in or associated with the discretionary use appliances 103 in the consumer premises 102. In the illustrated version, the communication is via wifi links 106. Other communications links may be used, including other wireless protocols such as ZigBee. Alternative communication means such as wired. Ethernet or powerline signalling systems may be used. A combination of communication links may be used, such that the hub has multiple communication transceivers.

Each of the discretionary use appliances 103 may include, or be associated with, an appliance control module 107. This appliance control module 107 includes a transceiver able to communicate with the hub 105, and means to control, at least in part, the power consumption of the appliance. The nature of this control will be dependent on the nature of the appliance. For appliances 103 such as non-variable speed pool pumps 108, only simple on/off control may be available. For HVAC equipment 104, the ability to control a thermostat setting may be included. Where the HVAC equipment 104 has zone controls, these may also be available to the appliance control module 107. The appliance control module 107 is able to communicate to the hub 105 the state of the controls to which it has access, and to receive instructions from the hub 105 to change the state of those controls. In further versions, the appliance control module 107 is also able to determine, and to communicate to the hub 105, the current power usage of the controlled device.

The appliance control module 107 enables an individual appliance to be controlled by the hub 105 in response to a price signal. It is advantageous to the energy utility 100 that as many appliances 103 as possible in the premises of the energy utility 100's customers be equipped with an appliance control module 107. Where the energy utility 100 is an electricity distribution network operator it is advantageous to the electricity utility 100 to have as many appliances 103 as possible in its operational geography include, or be associated with, an appliance control module 107. This opens up each appliance to a number of energy market participant bidders for their load.

The appliance control module 107 may be supplied as a unit independent of the appliance itself, or may be included as a part of the control circuitry of the appliance.

The appliance control module 107 may be completely separate from the controlled appliance and may control it by controlling the power supply to the appliance. The appliance control module 107 might be incorporated into a plug device which is plugged between the device and the GPO (general power outlet) to which the appliance is connected. The appliance control module 107 monitors the power being drawn from the GPO, and controls the device, on command from the hub 105, by cutting off the power supply from the GPO.

Where the appliance control module 107 is a separate unit supplied by an appliance control supplier, there is an additional cost which would usually be paid by the consumer receiving the appliance. Many consumers will not see the value in the appliance control module 107, or will be unable or unwilling to pay for an appliance control module 107. This may be the case even when the overall total cost of ownership of the appliance would be reduced by the provision of the appliance control module 107.

Where the appliance control module is included in the appliance prior to installation in a premises 102, or provided with the appliance by the appliance supplier, equipping an appliance with an appliance control module will increase the cost of the appliance to an appliance supplier. This increased cost would normally be passed on to the consumer as a price premium on the appliance purchase price. However, many consumers will not see greater value in the appliance equipped with the appliance control module 107 over a similar appliance not so equipped. Even where the consumer sees value, the consumer may not be able to afford the additional cost. Thus many consumers will be unwilling to pay the increased cost, and will purchase appliances 103 which are not appliance control module 107-equipped.

The installation of appliances 103 which do not have an appliance control module 107, either associated with the appliance or supplied as part of the appliance control circuitry, will reduce the number of appliances 103 available for a utility 100 to co-opt for changing power consumption. It is advantageous for the utility 100 to counter this reduction, and to have the greatest number of appliances 103 available to be controllable for power consumption change.

An appliance control supplier may be, without limitation, an appliance manufacturer, a manufacturer of control devices, an importer, a brand owner, a wholesaler and a utility 100.

The hub 105 is connected to an Intelligent Power Manager (IPM) 110. In a preferred version, this connection is via the internet, but other suitable communication systems, such as microwave or satellite links or a dedicated mesh network, may be employed. The IPM 110 is a hardware processor, or a process running on a computer, which is able to receive data from the hub 105 and from other sources, analyse the data and return data in response. The IPM 110 may be provided and controlled by a third party aggregator 112. The aggregator 112 is an intermediary between the household and the energy utility 100 (or any other energy network participant), providing the IPM 110 to multiple households and providing a service to the energy utility 100 of aggregating the relatively small power consumption change capabilities of those multiple households, to achieve the much larger power consumption changes needed by the energy utility 100. Alternatively, the IPM 110 may be provided directly by the energy utility 100.

It is advantageous to the aggregator 112 to provide a way to provide value to an appliance control supplier when that supplier's products are used in a consumption changing event. This value will make the provision of appliance control module 107 equipment attractive to the appliance control supplier, such that the price premium or additional cost may be reduced or eliminated. This will increase the number of appliances 103 in premises which are available for an aggregator 112 as load under control for consumption changing events. However, the aggregator 112 does not wish to pay for the provision of appliance controller modules which do not contribute to the aggregator 112's consumption change events. In order to provide this value to the appliance control supplier proportionally to the contribution to the aggregator 112's operation, the aggregator 112 accumulates a total of the power consumption changes which can be attributed to the appliance control modules 107 provided by a given appliance control supplier. The aggregator 112 then supplies value to the appliance control supplier in proportion to this accumulated total.

The hub 105 may include a user interface, allowing the consumer to interact with the hub 105. The hub 105 is able to identify, or have identified to it by a user, all of the discretionary use appliances 103 which it is able to control. This includes the nature of the available control in each case, and the power consumption characteristics of the appliance. This information is communicated to the Intelligent Power Manager (IPM) 110.

The energy utility 100 is also in communication with the Intelligent Power Manager (IPM) 110. This communication may be by any means and need not be continuous. Preferably, direct data communication occurs between a processing system of the energy utility 100 and the IPM 110.

Under particular load conditions, when particular supply and demand conditions exist for the energy utility 100, the energy utility 100 believes that a reduction in consumption of a particular amount would increase the return to the energy utility 100 by a sufficient amount that there is scope for providing a return to consumers and/or third parties for providing the consumption change. The requirement for such a consumption change is a demand response event. Preferably, this is a response to demand exceeding or threatening to exceed economical supply, and the required consumption change is a reduction in consumption.

The energy utility 100 formulates a price signal which is communicated to the intelligent Power Manager (IPM) 110. At its most basic, the price signal is an offer of something of value to the consumer in return for a change in electricity consumption for a given period. This may be as simple as raising the price of electricity for the period, with the “value” to the customer being the additional cost avoided by reducing consumption. However, the value may be in any form including but not limited to price reductions for electricity for this or some other period; direct money payments or bill reductions; goods, discounts on goods or vouchers for goods; services, discounts on services or vouchers for services; loyalty points redeemable for value; or any other offer which may be of value. Thus, there is an offered price in return for a required consumption change.

When the hub 105 is installed in the consumer premises 102 and/or at any later stage, the consumer interacts with the hub 105 to indicate what offer the consumer would accept to allow a particular control of the discretionary use appliances 103, and what limitations would be placed on that—that is, what consumption changes the household is capable of offering in a demand response event, and upon what conditions these consumption changes will be made available. These limitations may be specific to a particular appliance or the restrictions may be general, applying to any demand response in which the household is to participate. For example, without limitation, the householder may state they want a minimum 10% financial benefit on any demand response event, that is, the value received by the household in return for such participation must deliver at least a 10% reduction in total operational cost. Such a reduction must take into account the net control scenario, that is, any additional cost which may be incurred by having the appliance continue its function at a later time. These are the demand response parameters for the household.

For example, the consumer might indicate that any offer would be accepted to allow the pool pump to be turned off, so long as the pump would still run for a minimum specified number of hours for that day. Another specification might be that the air conditioning thermostat may be set one degree higher for a small discount offer, but up to five degrees higher for a large discount offer, but no change would be undertaken for any offer which is not money based. A further specification might be that for a still higher cash rebate, the air conditioner may be turned off, possibly with a limitation that this can only occur if the current temperature is less than a set value.

Further, the Intelligent Power Manager (IPM) 110 receives information from the hub 105 describing the electricity use of the household, and in particular the usage patterns of discretionary use appliances 103 which the hub 105 is able to control, at least in part. In general, this information will come from meters or submeters installed in the premises 102, but may come from other sources, including, without limitation, from suitably equipped appliance control modules 107. The IPM 110 uses this data to calculate other changes, not identified by the consumer, to discretionary appliance use which would be possible without causing undue inconvenience or discomfort to the household. These possibilities may be suggested to the householder for approval, or simply added as consumption change capabilities.

All of these consumption change capabilities and conditions together are the demand response parameters of the household as stored by the intelligent Power Manager (IPM) 110.

The more discretionary appliances 103 that are available for control by the hub 105, and the greater degree of control of those appliances 103 which is available, the greater the range of consumption change possibilities, and the more likely it will be that the household can participate in a given demand response event, and gain the value on offer.

The value available to the aggregator 112 is directly or indirectly related to the amount of consumption change which the aggregator 112 can deliver for the energy utility 100. It is therefore advantageous for the aggregator 112 to encourage as many appliances 103 within a household as possible to be able to be controlled by the hub 105, and to communicate electricity consumption and usage patterns to the hub 105.

The Intelligent Power Manager (IPM) 110 is connected to hubs 105 in multiple households in order to be able to deliver a significant consumption change to an energy utility 100. The sum of all of the consumption change capabilities in these households at any instant is the load under control for the aggregator 112 at that instant.

In order to increase the load under control, the aggregator 112 provides incentives to an appliance control supplier to provide an appliance control module 107 as part of any discretionary use appliance which the appliance control supplier supplies. These incentives are also provided to an appliance control supplier to encourage the supply of an appliance control module 107 to be associated with any discretionary use appliance which does not have an appliance control module 107 built-in. This incentive is in the form of a value transfer, to the appliance control supplier from the aggregator 112, proportional to the cumulative energy savings which can be attributed by the aggregator 112 to appliances 103 for which the appliance control supplier has supplied a built in or associated appliance control module 107.

In a preferred version the appliance control module 107 for a particular discretionary use appliance is integrated into the appliance at manufacture. The hub 105 and the intelligent Power Manager (IPM) 110 may include protocols necessary to communicate with the integrated appliance control module 107, or the hub 105 and the IPM 110 may be able to be programmed in the field, including by the appliance control module 107, to include the necessary communications protocols.

When a price signal is received by the Intelligent Power Manager (IPM) 110, the IPM 110 or the hub 105 calculates what demand response capabilities exist for the household within the parameters set by the price signal and the demand response parameters of the household. For each appliance, an attempt is made by the hub 105 or the IPM 110 to determine an optimal operating regime which allows participation in the demand response event in order to access the value offered by the price signal, while remaining within the predetermined household demand response parameters which provide for at least minimum acceptable function from the appliance. The combination of available responses for all appliances 103 is the household event response.

The hub 105 commands the appliance control module 107 of each appliance included in the household event response to undertake the required action to implement the optimal operating regime for that appliance, that is to turn off appliances 103, reduce thermostat settings or such other activities as were included in the household event response.

The hub 105 then monitors the reduction in power use by each of the affected appliances 103, for the period of time required by the demand response event. The actual reduction in consumption is then reported to the IPM 110.

The Intelligent Power Manager (IPM) 110 monitors the information returned by the hub 105 to ensure that the consumption reduction included in household event response is achieved by each participating discretionary appliance. The IPM 110 may receive data describing the energy consumption of an appliance from the hub 105, and the IPM 110 may calculate the reduction in power consumption of that appliance.

The Intelligent Power Manager (IPM) 110 includes memory 113 where the IPM 110 stores values which are cumulative records of the magnitude of the energy savings and/or the dollar value of the energy savings, which are attributed to all of the appliance control modules 107, or the appliance control module 107-equipped appliances 103 supplied by a given appliance control supplier, in all of the households where hubs 105 are operational.

Continuously or periodically, the aggregator 112 provides a value transfer to the appliance control supplier proportional to the value of the record held in memory 113 which records the cumulative energy saving which the Intelligent Power Manager (IPM) 110 has attributed to appliance control modules 107 or appliance control module 107-equipped appliances 103 supplied by the appliance control supplier to consumers connected to the IPM 110.

This total energy consumption change achieved by all the aggregator 112's households for the demand response event is reported to the energy utility 100. When the energy utility 100 is satisfied that the terms of the response to the demand response event have been met, the energy utility 100 makes available the promised value. Depending on the nature of the value, the energy utility 100 may provide the value to the participating consumers directly, or may provide it to the aggregator 112 for distribution to the participating consumers.

Although the description has been of an offer requiring consumption decreases, the price signal may be seeking to cause a consumption increase. The process would proceed in the same manner, but the outcome would be an increase in consumption. Examples of appliances 103 which might be turned on to increase demand would be storage hot water or space heaters, or pool pumps which had not yet run for the required hours for the day.

The appliance control module 107 may be incorporated into the hub 105 or into a separate device. There may be more than one device in a premises 102 having the functions of a hub 105, which may be in communication with each other, and may negotiate to share or surrender each of the hub 105 functions. For example, a device having hub 105 functionality may include an IR blaster, this being a device capable of emitting infra-red signals which emulate the signals of one or more appliance remote control devices. Such a device may allow control of a device which does not have an incorporated appliance control module 107, but which is able to be controlled by an IR remote control, such as a split system or single unit air conditioner. Since an IR blaster must be in line of sight of the controlled appliance, more than one such device may be needed in a premises 102, and it may be convenient for the supplied device to be the same device provided for hub 105 functionality.

Preferably, control of the appliance under the control of the hub 105 is provided by an appliance control unit. Operational data describing the operation and energy use of the appliance is provided by a data collection unit. In the example of the IR controlled device, the IR blaster is the appliance control unit. The data collection unit may be, without limitation, the utility meter of the premises 102, or a dedicated submeter. In other versions, the data collection unit may be incorporated in the appliance itself, or it may be provided by a plug load monitoring device.

The hub 105 may communicate to the aggregator 112 and/or the energy utility 100 in order to establish formats and parameter requirements which those parties may impose upon demand response event offers. Such requirements may require that the price requirement for a formal offer may be cash rebates, expressed in certain quanta. Alternatively, the only acceptable price offer might be in terms of fixed discounts per kWh for the duration of the demand response event. The hub 105 may include standard control packages for particular appliances 103, which may be applied by default when such an appliance is detected by the hub 105. These default packages are able to be altered or disabled by the consumer.

The hub 105 may be provided as a software package able to be run on a general purpose personal computer, where such personal computer has the necessary hardware and software to communicate with the discretionary use appliances 103 and the internet.

The general purpose personal computer may be a tablet computer including an iPad, or a handheld computing device such as a smartphone.

The hub 105 may be provided as a web site supplied by the aggregator 112, which may be accessed by a user using a general purpose web browser. In this case the discretionary use appliances 103 may be provided with means to individually access the internet in order to communicate with the hub 105. The web site may be hosted by the energy utility 100 itself.

The hub 105 and/or the Intelligent Power Manager (IPM) 110 may be integrated with the energy utility 100's processing and control systems.

The invention also includes a method of energy demand management using the controlled discretionary use appliances 103.

The method is a method by which an energy utility 100 with a need to change the energy demand which is being made upon the energy utility 100 at a particular time or for a particular time period, and a consumer with a requirement for energy which has a component which is discretionary as to the time the energy is required, or the quantity of energy required, to enter an arrangement whereby the consumer changes the demand made by the consumer upon the energy supplier in return for something of value provided by or on behalf of the energy utility 100.

The consumer sets parameters associated with one or more appliances 103 indicating what changes to the use of that device the consumer will make or allow in return for some nominated value. These may be such things as agreeing that a pool pump may be turned off in return for a cash rebate of a certain magnitude. Many other use changes could be agreed to.

When an energy utility 100 requires a consumption change, the energy utility 100 implements a demand response event, seeking a short term change in the level of demand the energy utility 100 is experiencing. The energy utility 100 formulates a price signal indicating the value which the energy utility 100 is prepared to offer for that change.

A hub 105 in the consumer's household, as shown in FIG. 1, may receive usage data from one or more discretionary use appliances 103 at times when the hub 105 is not exerting control over the appliances 103. This data details the use of the appliance when under the control of a user, including such information as time of day used, and settings used such as power levels or thermostat settings. Such data may also be gathered from appliances 103 whose use is not discretionary and which the hub 105 does not have the means to control. The hub 105 may also receive other data from other sensors or from other data sources including data such as ambient temperature, location of people within the house, and time of day, week, month and year.

The hub 105 uses the data to create a profile of the power use of each appliance and of the household overall, to the extent that the household usage data is available to the hub 105.

It may be advantageous for the hub 105 to have information concerning the total electricity usage of the household. Preferably, as shown in FIG. 1, the premises 102 has a Smartmeter 120 which performs the function of metering the electricity usage of the premises 102. The Smartmeter 120 includes a data communication capability which may be provided by any suitable wired or wireless protocol. Preferably the Smartmeter 120 includes ZigBee communication capability. The hub 105 may be “paired” with the Smartmeter 120, enabling the hub 105 to receive data detailing the electrical current flows into (or out of) the premises 102. The Smartmeter 120 may also include a wide area communication capability which may be a ZigBee mesh network or any other suitable wired or wireless communication capability.

In an alternative version, the Smartmeter 120 function is performed by a sub-meter installed in the household. The sub-meter includes, or is in communication with, current measuring devices such as “current clamps” which are placed around the incoming electricity conductors of the premises 102 and which allow the electrical current flowing to (or from) the premises 102 to be measured, and this information is made available to the hub 105.

The sub-meter may also measure the electricity consumption of a particular discretionary use appliance or group of appliances 103, where the appliance or group of appliances 103 are supplied by an individual circuit. In this case the sub-meter is the data collection unit collecting the operational data and providing the operational data to the hub 105.

Once a profile is established, the hub 105 may control the discretionary use appliances 103 under its control in order to maintain the profile. The hub 105 may further make changes to the usage profile in such a manner as to reduce overall power usage, or to shift power usage away from peak usage periods. This is done without input from the user. Each appliance and/or the hub 105 include means for a user to override the profile changes made by the hub 105. When a change is overridden, the hub 105 “learns” that the change was unacceptable to the user. Over time, the hub 105 develops an acceptable range for all controlled parameters of each appliance, having regard to such environmental factors such as ambient temperature, time and house occupancy, allowing the hub 105 to control appliances 103 for lower power use and/or off peak power use, without causing a nuisance to the user. This is the household management profile.

The override means may be the usual controls of the appliance, or dedicated controls to cancel the changes made by the hub 105 to the appliance settings may be provided.

At least some details of the household management profile are communicated to the Intelligent Power Manager (IPM) 110. This will include at least the information as to what power reductions could be made at any time without causing a nuisance to the householder. The IPM 110 aggregates the household management profiles of multiple households to build up profiles of actual and feasible use by region, by type of household, by time of day, week, month or year, by weather conditions, and by any other parameter which is measurable and is found to be relevant to power use. The IPM 110 may also know who are the energy utilities, distributors and generators associated with, or likely to be associated with each customer or customer group, and the data may also be aggregated against these parameters.

This aggregation allows the Intelligent Power Manager (IPM) 110 to determine predictions for energy usage across a given region or customer type for any period into the future, say the next 1, 12, 24, 36 and 48 hours. These predictions will include estimates of the likely variation range of the predicted power level. Over time the IPM 110 will develop predictions with increasing accuracy and with increasingly accurately predicted variation ranges. Any time period for prediction may be used, but very short or very long periods may be of lesser utility.

The hub 105 will also communicate to the intelligent Power Manager (IPM) 110 at least the predicted outcome of any changes to power consumption which the hub 105 is likely to initiate in the prediction period, based on the household management profiles.

These predictions may be made available to energy market participants for a consideration. These energy market participants may be energy utilities, energy generators, or energy distributors, each of whom have an interest in accurate predictions of demand over specific time frames.

These energy market participants already make predictions based on historical consumption data as measured by the distribution and generation systems. However, such predictions are unable to take account of individual household behavior, and particularly cannot account for changes introduced by the hub 105 in accordance with the household management profiles. The predictions made by the Intelligent Power Manager (IPM) 110 will thus be inherently more accurate than previous predictions.

Further, the Intelligent Power Manager (IPM) 110 will take account of previous price signals made, and the response of households to those price signals in the predictions provided. This is information which has not been available before.

Using the household management profiles, the Intelligent Power Manager (IPM) 110 is able to provide a new series of short term predictions based on the acceptance of any given price offer. This means that the energy market participants can receive a prediction of the downstream effects of any price offer. For example, it may be that a generous price offer that significantly reduces consumption at a peak period may be predicted to lead to an unacceptable peak some hours later when the appliances 103 whose use has been delayed are brought into use. As such, a less generous price offer, over a longer period may be better to meet the requirements of the entity making the price offer.

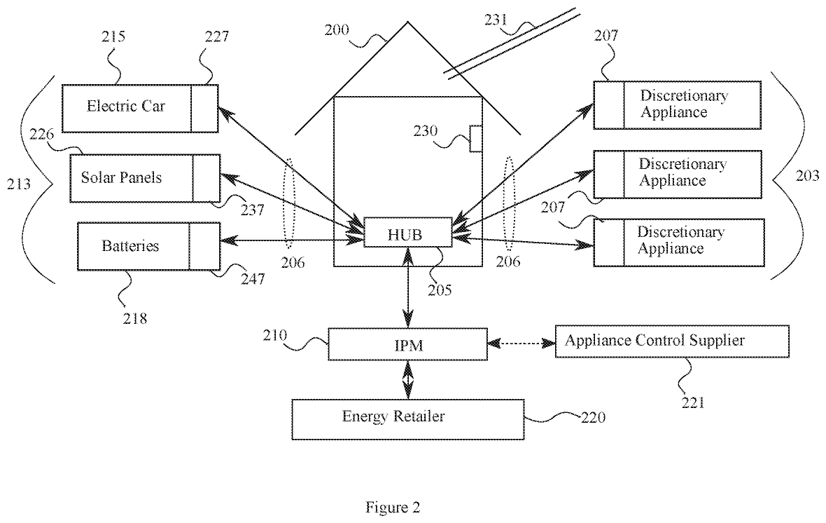

FIG. 2 depicts an energy retailer 220. The energy retailer 220 is responsible for sourcing electricity from generators of electricity (not shown) for supply to consumer premises 200. The electricity is provided to the consumer via electrical distribution grid 231.

The consumer has a demand for electricity to power one or more appliances including discretionary use appliances 203. The use, or degree of use, of these appliances 203 may be considered discretionary by the consumer. Such appliances 203 have a usage pattern which allows the overall function of the appliance to be achieved even with changes in the time or intensity of use.

A hub 205 is provided in the consumer premises 200. The hub 205 includes a communication transceiver which allows the hub 205 to communicate with corresponding transceivers in control circuitry in or associated with each of the discretionary use appliances 203 in the consumer premises 200. In the illustrated version, the communication is via wifi links 206. Other communications links may be used, including other wireless protocols such as ZigBee. Alternative communication means such as wired Ethernet or powerline signalling systems may be used. A combination of communication links may be used, such that the hub 205 has multiple communication transceivers. In further versions communication may be via the public internet.

Each of the discretionary use appliances 203 includes, or is associated with, an appliance control module 207. This appliance control module 207 includes a transceiver able to communicate with the hub 205, and means to control, at least in part, the power consumption of the appliance 203. The nature of this control will be dependent on the nature of the appliance 203. For appliances 203 such as pool pumps, only simple on/off control may be available. For HVAC equipment, the ability to control a thermostat setting may be included. Where the HVAC equipment has zone controls, these may also be available to the appliance control module 207. The appliance control module 207 is able to receive instructions from the hub 205 to change the state of those controls to which the module 207 has access. The appliance control module 207 may also be able to communicate the state of the controls to which it has access to the hub 205. In further versions, the appliance control module 207 is also able to determine, and to communicate to the hub 205, the current power usage of the controlled device.

Alternatively, the current power usage of the appliance 203 is communicated to the hub 205 by a data collection unit. The data collection unit may be, without limitation, the utility meter of the premises 200, or a dedicated submeter. In other versions, the data collection unit may be incorporated in the appliance itself, or it may be provided by a plug load monitoring device.

The hub 205 includes a user interface, allowing the consumer to interact with the hub 205. The hub 205 is able to identify, or have identified to it by a user, all of the discretionary use appliances 203 which it is able to control. This includes the nature of the available control in each case, and the power consumption characteristics of the appliance 203.

The hub 205 is able to connect to an Intelligent Power Manager (IPM) 210, supplied by a third party aggregator. In a preferred version, this connection is via the internet, but other suitable communication systems, such as, without limitation, a cellular data network, microwave or satellite links or a dedicated mesh network may be employed.

The energy retailer 220 is also in communication with the Intelligent Power Manager (IPM) 210. This communication may be by any means and need not be continuous. Preferably, there is direct data communication between a processing system of the energy retailer 220 and the IPM.

The energy retailer 220 may periodically implement demand response events, and communicate to the Intelligent Power Manager (IPM) 210 a corresponding price signal. When a price signal is received by the IPM 210, the IPM 210 or the hub 205 calculates what demand response capabilities exist for the household within the parameters set by the price signal and the household management profile. This is the household event response.

In response to the price signal, the hub 205 commands the appliance control module 207 of each appliance 203 included in the household event response to undertake the required action to turn off appliances 203, reduce thermostat settings, or such other consumption reduction activities as are available.

The hub 205 then monitors the reduction in power use by each of the affected appliances 203, passing this data to the Intelligent Power Manager (IPM) 210.

The Intelligent Power Manager (IPM) 210 monitors the data returned by the hub 205 to determine the contribution of each appliance 203 to the demand response event.

The Intelligent Power Manager (IPM) 210 is also in communication with at least one appliance control supplier 221.

The intelligent Power Manager (IPM) 210 stores values which are cumulative records of the magnitude of the energy savings, and/or the dollar value of the energy savings, which are attributed to all of the appliances 203 controlled by appliance control modules 207 supplied by a given appliance control supplier in all of the households where hubs 205 are operational.

Continuously or periodically, the aggregator provides a value transfer to the appliance control supplier which is proportional to the value of the record held in memory which records the cumulative energy saving which the Intelligent Power Manager (IPM) 210 has attributed to appliances 203 controlled by appliance control modules 207 supplied by the appliance control supplier to consumers connected to the IPM 210.

This value transfer is provided to incentivize the appliance control supplier to provide the appliance control module 207. This increases the pool of appliances 203 potentially available for control by the Intelligent Power Manager (IPM) 210 to respond to a demand response event.

Although the description has been of an offer requiring consumption decreases, the price signal may be designed to incentivize a consumption increase. The process would proceed in the same manner, but the outcome would be an increase in consumption. Examples of appliances 203 which might be turned on to increase demand would be storage water or space heaters, or pool pumps which had not yet run for the required hours for the day.

The appliance control module 207 for a particular discretionary use appliance 203 may be integrated into the appliance 203 at manufacture. This is advantageous for the aggregator, and is incentivized by the availability of payments to appliance control suppliers, the payments being related to the contribution to a demand response event of appliances 203 controlled by appliance control modules 207 supplied by an appliance control supplier. The hub 205 may include protocols necessary to communicate with the integrated or separate appliance control module 207, or the hub 205 may be able to be programmed in the field, including by the appliance control module 207, to include the necessary communications protocols.

The hub 205 may be provided as a web site supplied by the aggregator, which may be accessed by a user using a general purpose web browser. In this case the discretionary use appliances 203 may be provided with means to individually access the internet in order to communicate with the hub 205. In a version, the web site may be hosted by the energy retailer 220 itself.

Alternatively, the hub 205 and/or the intelligent Power Manager (IPM) 210 may be integrated with the energy retailer 220's processing and control systems.

Any function described as being performed by the hub 205 may be performed by the Intelligent Power Manager (IPM) 210. Conversely, any function described as being performed by the IPM 210 may be performed by the hub 205.

The premises 200 also has a number of associated storage and supply devices 213 which supply and/or store energy. These devices 213 are connected to the premises' electricity supply and may draw energy from the electrical supply, but are capable of supplying electricity to the premises' electrical supply.

These storage and supply devices 213 are also discretionary use appliances, with the primary or additional discretionary action of providing either load or supply to the grid.

A solar power installation 226 includes solar panels for generating electricity from energy provided by the sun, and associated electrical equipment for making that electricity available to the premises 200 and/or the electrical distribution grid. The amount of electrical power available to be supplied by the solar installation 226 at any moment varies depending upon the amount of sunlight available to the solar panels.

As with the other discretionary use appliances 203, the solar power installation 226 is in communication with the hub 205, in this case via a solar control module 237. The solar control module 237 is able to communicate data to the hub 205 concerning the electricity supply that the solar power installation 226 is making, or is capable of making, to the premises 200 or grid. Preferably, the solar control module 237 is also equipped to control the solar power installation 226 as to the fraction of the available power which the installation actually does supply to the grid or premises 200. The solar control module 237 may be provided as an integral part of the solar generation installation, or as a separate controller. There may be provided monitoring hardware independent of the solar installation which monitors the output of the solar installation, for example a separate meter which uses current clamps to measure the electrical energy being provided to the premises 200 electrical circuit by the solar installation 226 at any time. This measurement is provided to the hub 205, and hence to the intelligent Power Manager (IPM) 210.

A premises 200 having a generation capability, such as a solar power installation 226 or a wind power installation, may have the ability to supply excess electrical energy to the supply grid. For this, the premises 200's electrical supplier may pay a feed-in tariff. This feed-in tariff may be more than the tariff which the consumer pays for supply of electricity, in which case it is advantageous for as much of the solar power generation to be fed in to the grid as possible. Tariff information is supplied to the Intelligent Power Manager (IPM) 210 via the hub 205. The IPM 210 calculates the optimum usage of appliances 203 to maximize feed-in, taking into account the household management profile. The IPM 210 then instructs the hub 205 to control appliances 203 in accordance with the calculated usage, and/or provides information via the hub 205 to the consumer as to what usage should be made of appliances 203 to maximize feed-in to the grid.

Feed-in tariffs in excess of the supply tariff are less common than previously. The feed-in tariff may be less, often significantly less, than the supply tariff In this case, it is advantageous for the consumer to replace electricity drawn from the grid with locally generated electricity to the greatest extent possible. In this case the Intelligent Power Manager (IPM) 210 calculates the optimum usage of appliances 203 to maximize local consumption, taking into account the household management profile. This may involve running discretionary use appliances 203 during times when solar generation is available, and curtailing their use when such generation is not available. The IPM 210 then instructs the hub 205 to control appliances 203 in accordance with the calculated usage, and/or provides information via the hub 205 to the consumer as to what usage should be made of appliances 203 to minimize teed-in to the grid.

There is also a battery storage installation 218. Batteries act as a storage mechanism for electrical energy, able to act either as a load, drawing energy from the grid, or as an energy source supplying energy to the premises 200 and/or the grid. The battery storage installation 218 is in data communication with the hub 205 via a battery control module 247. The battery control module is able to communicate to the hub 205 the amount of power and energy which the battery installation 218 is drawing or supplying at any time. In a preferred version, the battery control module is able to provide data concerning the capacity of the battery to supply or draw energy at a given time. In a preferred version, the battery control module is then able to control the battery installation 218, under the control of the hub 205, to draw or supply energy.

Also associated with the premises 200 is an electric car 215 which may include an intelligent charging point. The electric car 215 has a battery of significant capacity. The car 215 draws electrical energy from the premises 200 to charge this battery, but it may also supply electrical energy from the battery to the premises 200 or the grid. The car 215 is in data communication with the hub 205 via car control module 227. The requirements of the car 215 regarding when it must have energy available for its primary transport function, and when it may be used as an energy source for the premises 200, are communicated to, or deduced by, the hub 205. This may be done by any combination of direct user input and profile building by the hub 205 based on past patterns of usage. The hub 205 would also require information concerning the charging time of the car 215, and any technical constraints on how quickly the car 215 may be charged or discharged. For example, a rule may be that the car 215 must be fully charged every weekday morning, but may be discharged during the early evening. This would allow the hub 205 to offer the supply capacity of the car to the intelligent Power Manager (IPM) 210 for the evening peak energy demand, even though the car 215 is not fully charged, while leaving adequate time for the car 215 to be charged during the nighttime low demand period to be fully charged by morning.

The functionality described for the electric car 215 may be provided by the electric car 215 alone, that is the car 215 has an integrated car control module, if the car 215 is equipped with the appropriate software, or it may be provided by a combination of the electric car 215 and an intelligent charging point.

It is not a requirement that the supply devices 213 be connected in such a way as to enable electricity to be fed back to the electricity supply grid. The electricity supplied by the supply device 213 may be used to reduce the demand by the premises 200 for electricity from the grid.

The addition of the storage and supply devices 213 increases the number and type of demand response events in which the hub 205 may participate.

The hub 205 is in communication with the Intelligent Power Manager (IPM) 210. The hub 205 in this version of the invention supplies information concerning the availability of a supply and storage capacity provided by the supply and storage devices 213. This information increases the range of demand response events which the IPM 210 may respond to. The availability of this alternative electrical power supply may allow the hub 205 to participate in demand response events by reducing usage of electricity supplied by the grid, without compromising the experience of the premises 200's occupants. Where a particular reduction in load is required, but no further discretionary use appliance loads are available to be switched off or their usage curtailed, the IPM 210 may draw some energy from the storage devices of the premises 200. From the point of view of the energy retailer 220, this is effectively the same as a load reduction, since it is energy which the retailer 220 no longer needs to source.

Conversely, when the price signal is one which calls for more energy to be used, the Intelligent Power Manager (IPM) 210 may command energy to be stored in the storage devices in the premises 200 for later use.

The suppliers of the electric car 215, the solar generation installation 226, and the batteries 218 are treated as appliance control suppliers. The aggregator desires that these storage and supply devices 213 include communication and control functionality which is accessible to the hub 205. This will increase the capability of the aggregator to respond to demand response events.

The contribution of the storage and supply devices 213 may be reduced consumption from the premises 200, or supply of electricity to the grid by the premises 200. The Intelligent Power Manager (IPM) 210 records the contribution of each individual storage and supply device 213 to each demand response event. Continuously or periodically, the IPM 210 transfers to the suppliers of these devices value proportional to the recorded contribution. In general this will be a monetary payment, but other valuable consideration may be used.

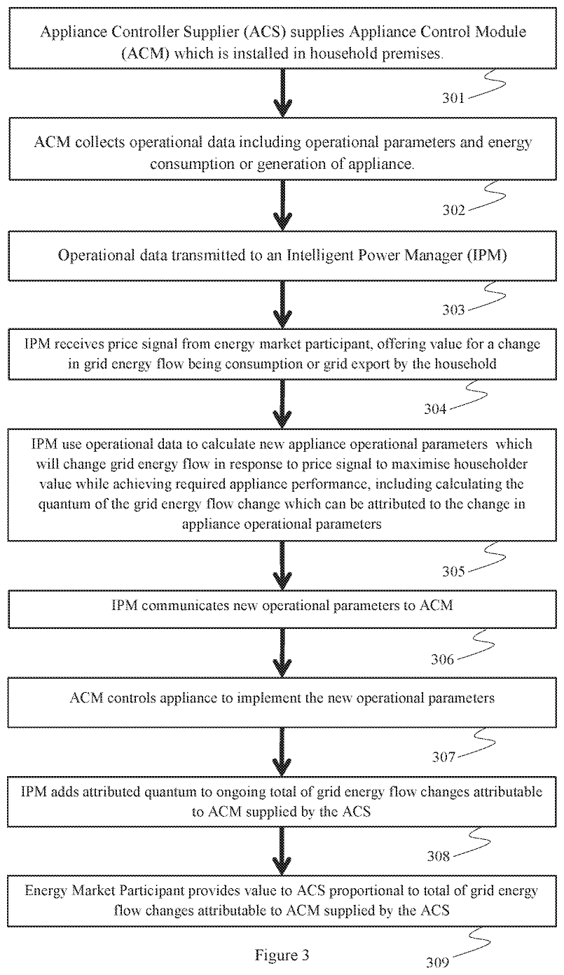

FIG. 3 presents is a flowchart of the process of recording the energy savings to be attributed to an appliance control supplier.

At 301, an appliance controller supplier supplies an appliance control module for installation in a premises. The appliance control module is any control device which allows remote control of some aspect of the appliance which affects the appliance's power consumption upon receiving a control signal from an external source. The external source may be an intelligent power manager, and/or a fully functional remote control for the appliance. In other versions the appliance control module may provide more limited control. For example, an air conditioner control may provide only an on/off function, rather than control of the thermostat settings.

For an energy market participant desiring to undertake a demand response event, for example an energy utility or a demand response aggregator, it is advantageous for as many devices as possible to have associated appliance control modules, in order for the devices to be controllable during the demand response event.

The appliance controller supplier may be the manufacturer of the appliance, in which case the appliance control module is likely to be integrated into the appliance. In other versions, the appliance controller supplier may be a third party supplier, supplying an add-on controller.

The appliance control module at 302 monitors the operation of the appliance and records operational data. This includes data about how the appliance is used, the operational parameters of the appliance and, in preferred versions, the energy consumption of the appliance. The operational data may also include information provided directly by a householder indicating the minimum performance parameters required of the appliance. The minimum performance parameters may include price information, indicating what price the householder would require in order to allow the performance to be reduced to the level of a particular performance parameter. Thus, for example, a small price might apply to changing an air conditioner's thermostat setting, while a larger price would be demanded if the air conditioner were to be turned off.

At 303, the operational data collected by the appliance control module is communicated to an Intelligent Power Manager (IPM). The IPM is computer code executing on a data processing system which includes a receiver, digital memory and a processor, which receives, stores and analyses the operational data.

At 304, the Intelligent Power Manager (IPM) receives a price signal from an energy market participant. The energy market participant may be any entity with an interest in changing the energy consumption of households supplied by an energy grid. This may include, without limitation, an electricity retailer, an electricity generator, an electricity distributor or grid operator, and an aggregator. An aggregator is an intermediary providing a service of aggregating the relatively small power consumption change capabilities of multiple households, to achieve the much larger power consumption changes needed for an effective demand response event. The price signal is an offer of something of value in return for a change in electricity consumption or generation for a given period.

At 305, the intelligent Power Manager (IPM) uses the operational data to calculate new appliance operational parameters which will change grid energy flow in response to the price signal to maximise householder value from the offered price while achieving the minimum required appliance performance for that offered price. The IPM calculates the quantum of the grid energy flow change which can be attributed to the change in appliance operational parameters.

At 306, the Intelligent Power Manager (IPM) communicates the new appliance operational parameters to the appliance control module. Preferably, this communication is via a hub device at the premises. Alternatively, communication may be direct.

The appliance control module receives the new operational parameters, and at 307, controls the appliance in accordance with these parameters. For example, a thermostat setting may be changed, or an appliance turned on or off.

The Intelligent Power Manager (IPM) adds the attributed quantum to a running total of grid energy flow changes attributable to appliance control modules supplied by the particular appliance control supplier. The IPM maintains a separate running total for each appliance control supplier who has an association with the entity hosting the IPM.

Periodically, the energy market participant responsible for the intelligent Power Manager (IPM) provides value to the appliance control supplier in proportion to the running total, which then resets. Preferably, the value provided is a cash payment. Other value transfers are possible.

The energy market participant responsible for the Intelligent Power Manager (IPM) is preferably an aggregator. In other versions of the invention, the responsible participant is an energy utility company. Other entities associated with the energy market may provide the IPM.

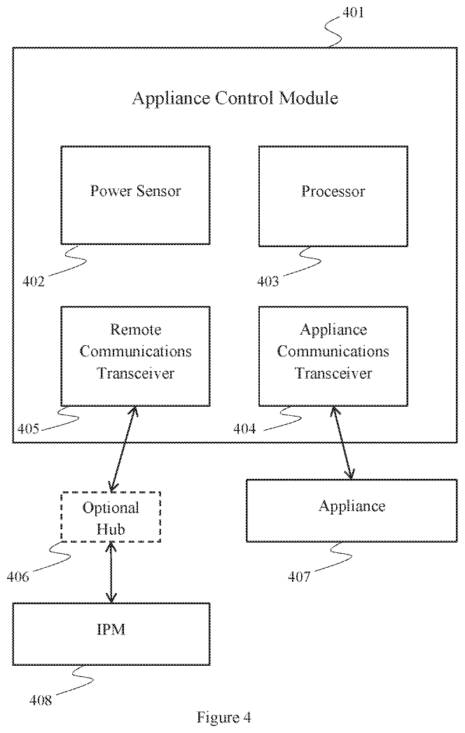

FIG. 4 is a diagrammatic representation of an appliance control module 401 of the versions of FIG. 1 and FIG. 2, wherein the appliance control module 401 controls an appliance 407.

The appliance control module 401 includes a power sensor 402 which senses the power being used by the appliance 407. Any form of power sensor known in the art may be used. Preferably, power to the appliance 407 flows through the appliance control module 401 and an inline sensor is employed. Alternatively, the appliance control module 401 may be adjacent to the appliance power supply and indirect sensors such as a Hall effect sensor may be used.

The appliance control module 401 includes an appliance communications transceiver 404 which communicates with the appliance 407. This may be a wireless transceiver or communication with the appliance 407 may be via a wired connection.

A remote communications transceiver 405 communicates with a remote Intelligent Power Manager (IPM) 408. This communication may be via a hub device 406 located within the premises where the appliance 407 is installed. In other versions, the hub 406 may be absent and the communication between the appliance control module 401 and the IPM 408 may be direct.

A processor 403 controls the appliance control module 401 and communication via the transceivers.

The appliance communications transceiver 401 may receive operational parameter values from the appliance 407 which describes the power state of the appliance, the values of any control parameters such as, without limitation, thermostat settings, power levels and operational programs. This is combined with the output of the power sensor to form the operational data which is transmitted to the Intelligent Power Manager (IPM) 408 by the remote communications transceiver 405.

The remote communications transceiver 405 receives from the intelligent Power Manager (IPM) 408 the details of the optimal operating regime calculated by the IPM 408 in response to a demand response event.

The processor 403 supplies control signals, via the appliance communications transceiver 404, to the appliance 407 to implement the optimal operating regime. Further operational data is transmitted to the Intelligent Power Manager (IPM) 408 which include output data from the power sensor 402 indicating the power used by the appliance 407 following implementation of the optimal operating regime. This data allows the IPM 408 to calculate the quantum of the grid energy flow change which can be attributed to the change in appliance operational parameters.

This flow change is then added to the running total being maintained for the supplier of the appliance control module 401.

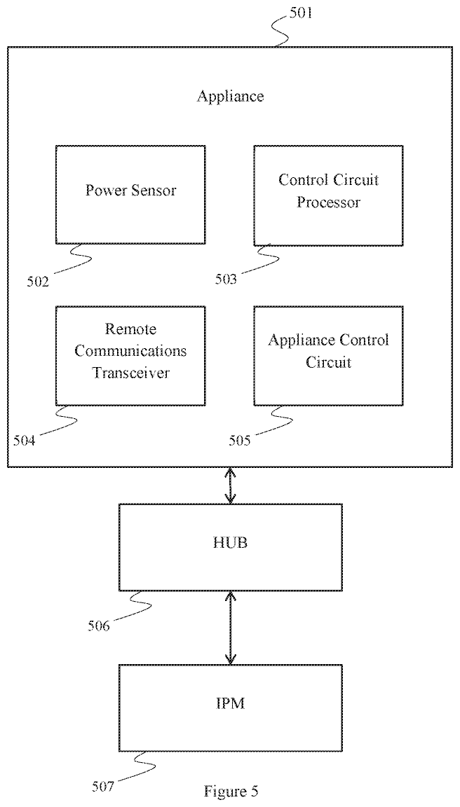

FIG. 5 is a diagrammatic representation of an appliance 501 incorporating elements of an appliance control module.

The appliance 501 includes a power sensor 502, which detects and outputs the power being drawn by the appliance 501. The operation of the appliance 501 is controlled by a control circuit processor 503 and is implemented by appliance control circuit 505. The processor 503 and the control circuit 505 control all aspects of the running of the appliance 501 in normal use. These components receive and implement the normal control actions of the appliance 501, such as, without limitation, a user turning the appliance 501 off or on, setting a thermostat, or setting an operational program.

The control circuit processor 503 gathers all of the control information describing how the appliance 501 is operated and combines this with the power sensor 502 output. This data is transmitted as operational data by a remote communications transceiver 504 to a locally provided communications hub 506. The communications hub 506 transmits this operational data to the Intelligent Power Manager (IPM) 507.

The remote communications transceiver 504 receives from the intelligent Power Manager (IPM) 507 the details of the optimal operating regime calculated by the IPM 507 in response to a demand response event.

The control circuit processor 503 controls the appliance control circuit 505 to implement the optimal operating regime for the appliance 505. Further operational data is transmitted to the Intelligent Power Manager (IPM) 507, which include output data from the power sensor 502 indicating the power used by the appliance 501 following implementation of the optimal operating regime. This data allows the IPM 507 to calculate the quantum of the grid energy flow change which can be attributed to the change in appliance operational parameters. This flow change is then added to the running total being maintained for the supplier of the appliance, who in this case is the supplier of the appliance control module.

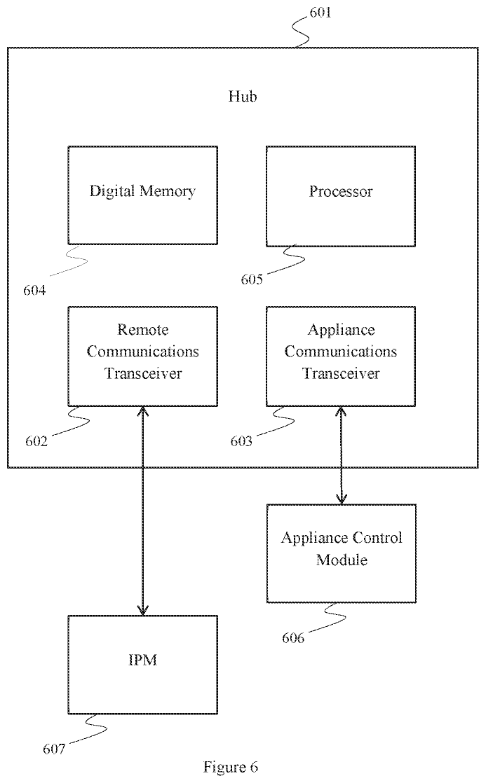

FIG. 6 is a diagrammatic representation of a hub 601 as described above with associated connections.

The hub 601 includes a processor 605 and digital memory 604. The hub 601 is in communication with an intelligent Power Manager (IPM) 607 via remote communications transceiver 602. The remote communications transceiver 602 may be any suitable communications link, including, without limitation, wired and wireless connections, an internet connection, and connection via a cellular telephony network.

The hub 601 is in communication with an appliance control module 606 via appliance communications transceiver 603. This communication may be via any suitable communication means, including, without limitation, a Zigbee communication link, and a wired communication link.

Where the premises is a domestic household, the hub 601 is able to learn the energy requirements of the household and to control energy usage to achieve the minimum overall cost for that energy. The hub 601 has the ability to monitor, learn and control key energy loads in the home without creating any, or at leak minimal, householder nuisance.

The hub 601 is able to build a profile of a household for different weather conditions, time of day, day of week and home occupancy events. The hub 601 determines load saving and load shifting opportunities which it may execute automatically, but providing a means for the householder to override or opt out from any changes made to the operation of any appliance.

The intelligent Power Manager (IPM) 607 provides aggregation of this energy usage information over a number of homes, preferably a large number of homes. The IPM 607 may build profiles of typical household energy use to build household energy usage by various criteria such as size, location or any other suitable criteria. The IPM 607 may group households by region/load profile/etc. This information may be used by an aggregator to facilitate energy utilities acquiring customers whose energy use is complementary to the energy use patterns of other of the utility's customers such that overall, the total load profile for the utility more closely matches the optimum load profile for the utility's profitability.

The Intelligent Power Manager (IPM) 607 is thus able to provide rolling twenty-four hour predictions of energy usage levels across all aggregated homes, or across only customers of a particular utility or generator or distributor; or only those customers in a particular region; or those households of a particular makeup, that is, across any grouping where that information might be of value to another market participant.

These predictions would be augmented with information on energy usage adjustment opportunities either per household or preferably aggregated so as to present to the interested market participant (utility/generator/distributor/etc) information as to what energy load shifting is possible with a price offer presented to the aggregator for implementation in the aggregated households.

The IPM may present information to the market participant as to the price offer which would be required from that market participant to increase or decrease loads by a certain level based on the household loads which the aggregator is able to control via the IPM and the household hubs.

The rolling forecast can be updated with any changes in the predicted household loads which will occur because of the household accepting any price offer to increase or decrease loads.

This rolling twenty-four hour information may be used by the market participant as the basis for action in the energy trading market.

The illustrated versions refer to energy utilities, but any energy market participant may be the counterparty. The energy market participant may be, without limitation, one or more of an energy utility, a grid operator, an electricity generator, an electricity consumer, a participant in a peer to peer electricity exchange, and an energy market regulator.

Although the invention has been herein shown and described in what is conceived to be the most practical and preferred version, it is recognised that departures can be made within the scope of the invention, which is not to be limited to the details described herein but is to be accorded the full scope of the appended claims so as to embrace any and all equivalent devices and apparatus.

1. A method for control of an electrical appliance in a household premises, the method utilizing:
A. an electrical appliance at the premises,
B. an appliance control module associated with the electrical appliance, the appliance control module receiving appliance operational data characterizing the electricity usage of the appliance,
C. a hub in data communication with the appliance control module,
D. an intelligent power manager in data communication with:
(I) the hub, and
(II) an energy market participant,
The method including the steps of:
a. the hub receiving the appliance operational data from the appliance control module,
b. the intelligent power manager:
(1) receiving:
i. the appliance operational data from the hub, and
ii. a price signal from an energy market participant, the price signal characterizing value to be provided to the premises for a change in the amount of electricity to be supplied to the premises,
(2) processing the appliance operational data and the price signal to determine an optimized appliance operating regime which maximizes the value to be provided to the premises while ensuring that the electrical appliance meets defined appliance operational requirements,
c. the hub:
(1) controlling the electrical appliance to follow the optimized appliance operating regime, thereby changing the electrical appliance's electricity usage,
(2) receiving the electrical appliance's changed electricity usage, and
(3) communicating to the intelligent power manager the electrical appliance's changed electricity usage,
d. the intelligent power manager:
(1) recording a value for the electrical appliance's changed electricity usage,
(2) adding the value to other values for changed electricity usage arising from other electrical appliances, the other electrical appliances each having an associated other appliance control module, thereby obtaining a total value for changed electricity usage.

2. The method of claim 1 wherein:
a. the appliance control module associated with the electrical appliance, and
b. the other appliance control modules associated with the other electrical appliances,
are provided by an appliance control supplier.

3. The method of claim 2 further including the step of making a value payment to the appliance control supplier, the value payment being dependent on the total value for changed electricity usage.

4. The method of claim 2 wherein:
a. the appliance control supplier is a manufacturer of the electrical appliance, and
b. the appliance control module is incorporated into the electrical appliance at manufacture.

5. The method of claim 1 wherein the step of the hub controlling the electrical appliance includes:
a. the hub providing control signals to the appliance control module, and
b. the appliance control module changing the electrical appliance's electricity usage in dependence on the control signals.

6. The method of claim 1 wherein the operational data characterizing the electricity usage of the appliance includes at least one of:
a. data characterizing any electricity consumption by the appliance.
b. data characterizing any electricity generation by the appliance.

7. The hub unit of claim 1 wherein the appliance control module is separate and spaced from the electrical appliance.

8. The method of claim 1 wherein the hub includes:
a. an appliance communications transceiver configured to:
(1) receive the appliance operational data from the appliance control module, and
(2) transmit control signals to the appliance control module, the control signals controlling the electrical appliance to follow the optimized appliance operating regime,
b. a remote communications transceiver configured to:
(1) transmit the appliance operational data to the intelligent power manager, and
(2) receive the optimized appliance operating regime from the intelligent power manager.

9. A hub unit for installation in a household premises, the hub unit including:
A. an appliance communications transceiver configured to communicate with an appliance control module, the appliance control module being:
(I) supplied by an appliance control supplier, and
(II) configured to receive appliance operational data from an associated electrical appliance installed within the premises, the appliance operational data characterizing the electrical appliance's electricity usage,
B. a remote communications transceiver configured to communicate with a remote intelligent power manager, the intelligent power manager being configured to:
(I) receive from an energy market participant a price signal offering to the premises a value for a change in the amount of electricity to be supplied to the premises in a future time period, and
(II) process the appliance operational data and the price signal to determine an optimized appliance operating regime which maximizes the value offered to the premises while ensuring that the appliance meets defined operational requirements,
wherein the hub unit is configured to:
a. receive the appliance operational data from the appliance control module via the appliance communications transceiver,
b. transmit the appliance operational data to the intelligent power manager via the remote communications transceiver,
c. receive data from the intelligent power manager via the remote communications transceiver, the data characterizing the optimized appliance operating regime,
d. control the electrical appliance to change the electrical appliance's electricity usage to follow the optimized appliance operating regime, and
e. transmit the electrical appliance's changed electricity usage to the intelligent power manager via the remote communications transceiver,
and wherein the intelligent power manager is configured to:
a. record a value for the electrical appliance's changed electricity usage, and
b. add the value to other values for changed electricity usage arising from other electrical appliances, the other electrical appliances each having an associated other appliance control module supplied by the appliance control supplier, thereby obtaining a total value for changed electricity usage,
whereby a value payment can be made to the appliance control supplier proportional to the total value.

10. The hub unit of claim 9 wherein:
a. the appliance control supplier is a manufacturer of the electrical appliance, and
b. the appliance control module is incorporated into the electrical appliance at manufacture.

11. The hub unit of claim 9 wherein the appliance control module is separate and spaced from the electrical appliance.

12. A system for control of an electrical appliance in a household premises, the system including:
a. a hub configured to:
(1) be in data communication with an appliance control module:
i. associated with the electrical appliance, and
ii. supplied by an appliance control supplier,
(2) receive appliance operational data from the appliance control module characterizing the electricity usage of the appliance, and
(3) provide control signals to the appliance control module to control the electricity usage of the appliance,
b. an intelligent power manager configured to:
(1) receive from an energy market participant a price signal offering to the premises a value for a change in the amount of electricity to be supplied to the premises in a future time period,
(2) receive the appliance operational data from the hub,
(3) process the appliance operational data and the price signal to determine an optimized appliance operating regime which maximizes the value received by the premises while ensuring that the appliance meets defined operational requirements,
c. the hub further being configured to:
(1) control the electrical appliance to change the electrical appliance's electricity usage to follow the optimized appliance operating regime,
(2) receive the electrical appliance's changed electricity usage, and
(3) communicate to the intelligent power manager the electrical appliance's changed electricity usage,
d. the intelligent power manager further being configured to:
(1) record a value for the changed electricity usage, and
(2) add the value to other values for changed electricity usage arising from other electrical appliances, the other electrical appliances each having an associated other appliance control module supplied by the appliance control supplier, thereby obtaining a total value for changed electricity usage.

13. The system of claim 12 wherein the intelligent power manager is further configured to make a value payment to the appliance control supplier, the value payment being proportional to the total value for changed electricity usage.

14. The system of claim 12 wherein the appliance control module is incorporated into the appliance at manufacture and the appliance control supplier is a manufacturer of the appliance.
a. the appliance control module is incorporated into the electrical appliance at manufacture, and
b. the appliance control supplier is a manufacturer of the electrical appliance.

15. The system of claim 12 wherein the appliance control module is separate and spaced from the electrical appliance.
